(19) United States
(12) Patent Application Publication
(10) Pub. No.: US 2012/0109397 A1
(43) Pub. Date: May 3, 2012

(54) LOCATION-BASED SMART ENERGY MANAGEMENT SYSTEM USING RFID AND METHOD THEREOF

(75) Inventors: Youn Min SHIM, Seoul (KR); Heung-Soo Park, Namyangju Si (KR)

(73) Assignees: HANWHA SOLUTION & CONSULTING CO., LTD, Seoul (KR); ezVille CO., LTD, Seoul (KR)

(21) Appl. No.: 12/946,508

(22) Filed: Nov. 15, 2010

(30) Foreign Application Priority Data
Oct. 29, 2010 (KR) 10-2010-0107007

(51) Int. Cl. G06F 1/28; G01R 21/00

(52) U.S. Cl. 700/295; 702/62

(57) ABSTRACT

In a smart energy management system linked with home network devices respectively installed in a plurality of households to manage the use of energy for each household, a location detecting unit detects location information or entry/exit information of a household member through recognition of an RFID tag carried by the household member connected with an RFID receiving device. An energy recording unit receives energy use details of the household, inputted from the home network device, and records the received energy use details together with the location information or entry/exit information of the household member. A pattern analysis unit analyzes an energy use pattern for the energy use details. An energy management unit provides the energy use details through the home network device as a result obtained by comparing the energy use detailed for each household or so that the household member recognizes the energy use pattern.

### PRIORITY

This application claims the benefit of Korean Patent Application No. 10-2010-0107007, filed on Oct. 29, 2010 in the Korean Intellectual Property Office, the disclosure of which is incorporated herein by reference.

### BACKGROUND

1. Field of the Invention

The present invention relates to a location-based smart energy management system and a method thereof, which can automatically manage energy for each household in a multiplex building.

2. Description of the Related Art

A building automation and control network (BACnet) that is a Korean standard (KS) related to building automation and control communication network tends to be applied to a multiplex building divided into a plurality of spaces, such as an apartment building, condominium, hotel or boarding house.

The BACnet is applied to the multiplex building as described above, so that it is possible to facilitate the addition, maintenance, and management of a building automation system and to reduce expenses required for the operation of the building automation system, thereby ensuring economic stability.

As climate change and energy problems have recently appeared as global challenge problems, power consumption and carbon emission is on the rise as an important issue.

Therefore, in addition to the building automation system, conducting studies on an energy management system for managing the use of energy for each household by detecting the energy use pattern of each household member so as to save energy is desired.

### SUMMARY

An aspect of the present invention provides a smart energy management system and method capable of detecting an energy use pattern for each household in a multiplex building divided into a plurality of spaces.

An aspect of the present invention also provides a smart energy management system and method capable of providing an optimized energy control mode for each household member by detecting an energy use pattern for each household, and supporting active management for the amount of energy used.

According to an aspect of the present invention, there is provided a smart energy management system linked with home network devices respectively installed in a plurality of households to manage the use of energy for each household, the system including a location detecting unit to detect location information or entry/exit information of a household member through recognition of a radio frequency identification (RFID) tag carried by the household member in connection to an RFID receiving device, an energy recording unit to receive energy use details of the household in which the household member resides, inputted from the home network device, and to record the received energy use details together with the location information or entry/exit information of the household member, a pattern analysis unit to analyze an energy use pattern for the energy use details based on the location information or entry/exit information, and an energy management unit to provide the energy use details through the home network device as a result obtained by comparing the energy use detailed for each household or so that the household member recognizes the energy use pattern.

The energy recording unit may record the energy use details for each household member with respect to a plurality of household members that reside in the household, and the pattern analysis unit may manage energy use patterns for the plurality of household members by combining the energy use details recorded for each household.

When the energy use amount of the household exceeds a predetermined value and the household member does not operate a home appliance through the home network device due to a predetermined condition, the energy management unit may directly control the home appliance through the home network device.

According to an aspect of the present invention, there is provided a smart energy management method of a smart energy management system linked with home network devices respectively installed in a plurality of households to manage the use of energy for each household, the method including detecting location information or entry/exit information of a household member by recognizing an RFID tag carried by the household member through an RFID receiving device, receiving energy use details of the household in which the household member resides, inputted from the home network device, and recording the received energy use details together with the location information or entry/exit information of the household member, analyzing an energy use pattern for the energy use details based on the location information or entry/exit information, and providing the energy use details through the home network device as a result obtained by comparing the energy use detailed for each household or so that the household member recognizes the energy use pattern.

As described above, according to embodiments of the present invention, the location or presence of entry/exit of a household member in a household is detected, and energy use details of the corresponding household are recorded, so that an energy use pattern of the household member may be easily detected based on the location or presence of entry/exit of the household member.

Also, home appliances in the household are automatically controlled to be suitable for the energy use pattern detected from the energy use details of the household member, so that a home network service optimized to the household member may be provided.

Also, an energy use pattern for a plurality of household members are separately managed by combining energy use details for each household member in a household in which the household members reside, so that even when several household members reside in the household, energy in an optimized state may be managed.

Also, a result obtained by comparing an energy use amount of a household with an energy use amount of another household is provided, so that a motive for energy saving may be provided to a household member using a large amount of energy, and a household indifferent to energy management may be guided to save energy in an active manner.

Thus, an energy saving management system capable of effectively managing energy used for each household with respect to a plurality of households may be built, and consequently, each household member may benefit.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a diagram illustrating a relationship among a radio frequency identification (RFID) receiving device, a home network device, and a smart energy management system according to an embodiment of the present invention;

FIG. 2 is a block diagram illustrating an internal configuration of a smart energy management system for managing the use of energy by analyzing the energy use pattern of a household based on recognition of the location of a household member according to an embodiment of the present invention; and

FIG. 3 is a flowchart illustrating a smart energy management system for managing the use of energy by analyzing the energy use pattern of a household based on recognition of the location of a household member according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

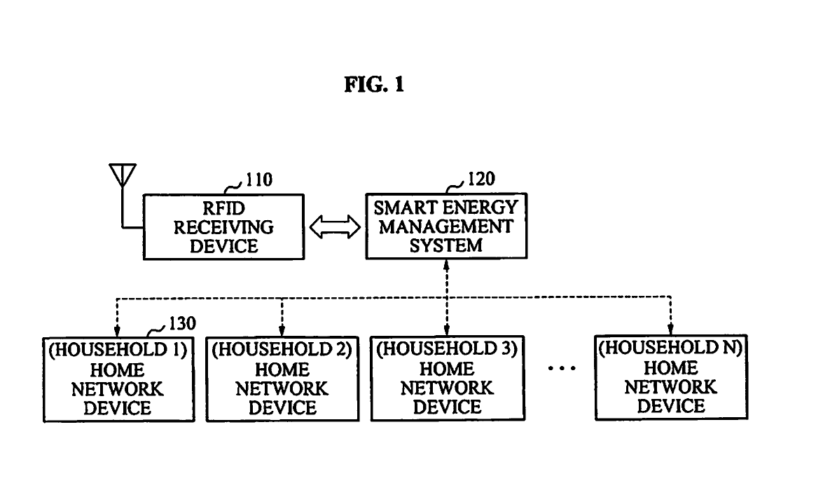

FIG. 1 is a diagram illustrating a relationship among a radio frequency identification (RFID) receiving device, a home network device, and a smart energy management system according to an embodiment of the present invention. FIG. 1 illustrates a smart energy management system 120 linked with an RFID receiving device 110 and a home network device 130 among a plurality of home network devices.

The smart energy management system 120 performs an energy saving control for preventing energy from being wasted in each household with respect to a multiplex building composed of a plurality of households. To prevent energy from being wasted, the smart energy management system 120 may be configured to be linked with the RFID receiving device 110 and the home network device 130 of the plurality of households (household 1 to household n).

The RFID receiving device 110 may be configured as at least one RFID reader installed inside or outside of a household to recognize an RFID tag carried by a household member when the household member approaches the household. As an example, the RFID receiving device 110 may transmit location information of a household member with an RFID tag in a household to the smart energy management system 120 via an access point through a radio connection.

The home network device 130 refers to a medium installed inside a household to perform a central control with respect to home appliances. As an example, the home network device 130 may be configured as a home network wall-pad used by being attached to the surface of a wall in a kitchen or living room of a household. Here, the home network wall-pad is basically configured in the form of a touch screen to provide an interface function with household members. In addition to functioning as a door intercom, the home network wall-pad provides various functions of crime prevention, disaster prevention and home appliance control, in addition to video communication between households, Internet connection, TV watching, and the like. That is, the home network device 130 may perform a central control with respect to home appliances in a household by maintaining connections to the home appliances through a wired/wireless communication interface. Here, the home appliances may comprehensively include all devices using energy, such as cooling/heating devices, home electronics, and lighting devices. Particularly, the home network device 130 may monitor energy use details such as a power on/off time or state for each home appliance, the amount of energy used for each home appliance and the total amount of energy used in a household, and may transmit the energy use details to the smart energy management system 120 at the same time. In this instance, the home network device 130 may transmit not only energy use details manually inputted by a household member but also energy use details to be automatically analyzed by the smart energy management system 120. The home network device 130 may also control the power and operation of home appliances in a household under the control of the smart energy management system 120.

That is, the smart energy management system 120 may perform a central control with respect to energy used in a plurality of households. The smart energy management system 120 may provide a service for detecting the location of a household member for each household and managing energy consumption of the household according to an energy use pattern based on the location of the household member, by being linked with the RFID receiving device 110 and the home network devices 130 of the plurality of households (household 1 to household n).

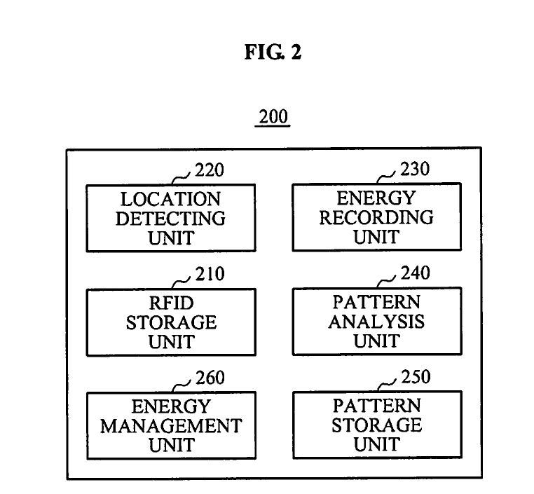

Hereinafter, the detailed configuration and function of a smart energy management system according to an embodiment of the present invention will be described with reference to FIG. 2.

FIG. 2 is a block diagram illustrating an internal configuration of a smart energy management system 200 for managing the use of energy by analyzing the energy use pattern of a household based on recognition of the location of a household member according to an embodiment of the present invention.

As illustrated in FIG. 2, the smart energy management system 200 according to this embodiment may include RFID storage unit 210, a location detecting unit 220, an energy recording unit 230, a pattern analysis unit 240, a pattern storage unit 250 and an energy management unit 260.

The RFID storage unit 210 may store and maintain an identification code of an RFID tag carried by a household member in connection with personal information of the household member. In this instance, the identification code is a code value for distinguishing the household member from other household members, and the personal information may include identification information for distinguishing a household in which the household member resides from other households, and the like. For example, in the case of a multiplex building such as an apartment building, the RFID storage unit 210 may store an identification code of an RFID tag carried by a household member and a building/house number of a corresponding household by matching the household member and the building/house number. The RFID storage unit 210 may also store and maintain identification information of an RFID reader that constitutes the RFID receiving device 110 and location information of the RFID reader by matching the identification information and the location information.

The location detecting unit 220 may detect location information or entry/exit information of a household member through recognition of an RFID tag carried by the household member in connection with the RFID receiving device 110. As an example, in a case where the RFID receiving device 110 detects location information or entry/exit information of a household member and transmits the detected location information or the entry/exit information to the smart energy management system 200, the location detecting unit 220 may receive the transmitted location information or entry/exit information of the household member from the RFID receiving device 110. As another example, in a case where the RFID receiving device 110 recognizes an RFID tag of a household member and transmits an identification code of the recognized RFID tag together with identification information of an RFID reader that recognizes the RFID to the energy management system 200, the location detecting unit 220 may receive the identification code of the RFID tag and identification information of the RFID reader from the RFID receiving device 110 so as to detect location information or entry/exit information of the household member. Specifically, the location detecting unit 220 may recognize personal information of a household member, corresponding to an identification code of an RFID tag carried by the household member, based on a data stored in the RFID storage unit 210 so as to detect the presence of entry/exit of the household member. In addition, the location detecting unit 220 may recognize location information of an RFID reader, corresponding to identification information of the RFID reader, based on a data stored in the RFID storage unit 210 so as to detect the recognized location information as location information of a household member.

The energy recording unit 230 may receive energy use details of a household, inputted from the home network device 130 installed in the household in which a household member resides, and record the energy use details together with the location information or entry/exit information of the household member. In this instance, the energy recording unit 230 may manage energy use details for each household member based on household member information distinguished according to a code value of the RFID tag. The energy recording unit 230 can minimize a data dispersion phenomenon caused by outliers by using several filters in collection of energy data related to heating and the like from the home network device 130.

The pattern analysis unit 240 functions to analyze an energy use pattern of a household member with respect to energy use details based on location information or entry/exit information of the household member. As an example, the pattern analysis unit 240 may detect an energy use pattern of a household member by analyzing energy use details of the household member. For example, the pattern analysis unit 240 may analyze a time when a household member enters/exits from/to the outside, and detect that the household member does not use a lighting device during the corresponding time even though the lighting device is turned on or turned off when the household member enters/exits from/to the outside. Alternatively, the pattern analysis unit 240 may analyze a time when a lighting device is used while a household member stays in a household, and detect that the household member uses the lighting device during the corresponding time. As another example, the pattern analysis unit 240 may detect an energy use pattern of a household member by simply accumulating energy use details of the household member. For example, the pattern analysis unit 240 may accumulate the energy use amount of a household member by defining a week as a period and detect an energy use pattern of the household member for a predetermined period through an amount of energy used for each period. As still another example, in a case where a plurality of household members reside in a household, the energy recording unit 230 records energy use details of a corresponding household member for each household member. In this instance, the pattern analysis unit 240 may analyze an energy use pattern obtained by combining a set of energy use details recorded for each household member. For example, the time including a time when a first household member uses a lighting device and a time when a second household member uses the lighting device may be separately managed as an energy use pattern for the plurality of household members. As still another example, the pattern analysis unit 240 may recognize energy use details when a household member is alone in the household and an energy variation newly generated by tracing a variation when an additional household member is in the household as an energy use pattern of the additional household member.

The pattern storage unit 250 may store and manage an energy use pattern for each household or for each household member. That is, the pattern storage unit 250 may store an energy use pattern analyzed for each household member, or may separately manage an energy use pattern obtained by combining a set of energy use patterns analyzed for a plurality of household members.

The energy management unit 260 may provide energy use details through the home network device 130 as a result obtained by comparing the energy use detailed for each household or so that the household member recognizes the energy use pattern. As an example, the energy management unit 260 may transmit, to the home network device 130, a result obtained by comparing energy use amounts of households having the same number of household members. This may be approached in view of ‘waste’ and ‘personal situation’ with respect to a difference between energy use amounts of households, obtained by comparing an energy use amount for each household. Specifically, in a case where the energy use amount of a specific household exceeds a predetermined value, the energy management unit 260 may analyze whether the factor is derived from indifference to saving energy or a personal situation. In a case the factor is derived from the indifference to saving energy, the energy management unit 260 may guide the household to save energy using an active method through the home network device 130. In this instance, the condition determined as indifference to energy management may indicate that a household member does not operate a home appliance through the home network device 130 due to a predetermined condition. For example, in a case where a household member rarely manually controls the temperature of a room, a case where the household member does not make a separate setup for heating in absence, or a case where any one of the plurality of household members rarely performs an operation, may be determined as being indifferent to energy management. As described above, the energy management unit 260 may automatically detect an energy use pattern based on a basic determination reference, and allow a household member to monitor and change an energy use amount through the home network device 130 with respect to a more detailed setup. A method of guiding a household member to save energy as an active method may indicate that the household member directly controls home appliances in a household through the home network device 130. For example, if a heating device is operated even when away from home, a household member may turn off the power of the heating device through the home network device 130. In addition, in a case where the excess of an energy use amount in a predetermined household does not correspond to indifference to saving energy, the energy management unit 260 controls the home network device 130 to inform that the energy use amount of the specific household is greater than that of another household, as opposed to performing a direct control of a home appliance. As another example, the energy management unit 260 may simply provide an energy use pattern of a household member in a graphic form through the home network device 130 so that the household member can monitor his/her own energy use pattern. As still another example, the energy management unit 260 may transmit control information based on an energy use pattern of a household member to the home network device 130. In this instance, the home network device 130 may automatically control home appliances in a household based on the control information received from the energy management unit 260. For example, in a case where a specific household member has an energy use pattern of changing all home appliances in a household into an energy saving state from 9 am to 6 pm, the energy management unit 260 may transmit a control signal corresponding to the corresponding energy use pattern to the home network device 130, and the home network device 130 may allow the home appliances in the household to be saved based on the energy use pattern of the household member under the control of the energy management unit 260.

The smart energy management system 200 having the aforementioned configuration can provide an optimized energy control mode suitable for a household member in a household by detecting the location (or presence of entry/exit) and energy use pattern of the household member in real time. In addition, the smart energy management system 200 can guide a household to save energy or directly control home appliances of the household so as to reduce energy use cost.

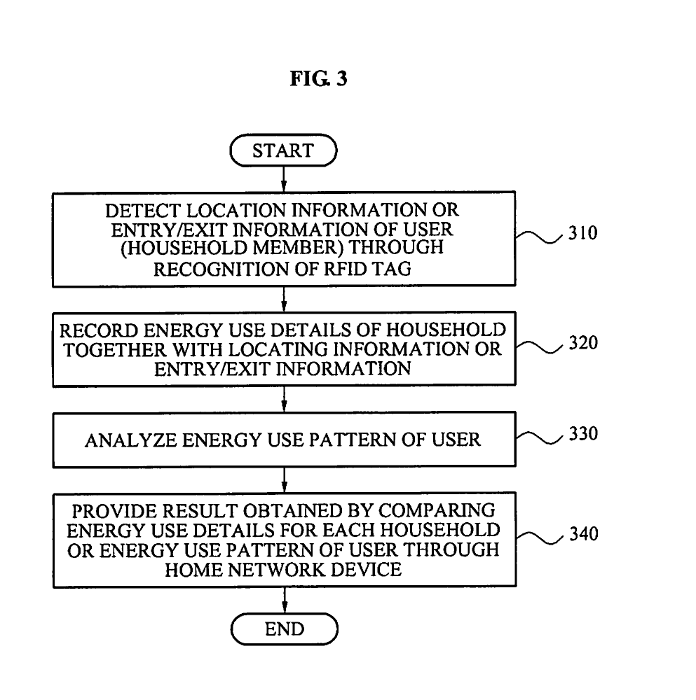

FIG. 3 is a flowchart illustrating a smart energy management system for managing the use of energy by analyzing the energy use pattern of a household based on recognition of the location of a household member according to an embodiment of the present invention. In the smart energy management method according to the present embodiment, operations can be sequentially performed by the smart energy management system 200 described with reference to FIG. 2.

In operation S310, the smart energy management system 200 may determine location information or entry/exit information through recognition of an RFID tag carried by a household in connection with the RFID receiving device 110. As an example, in a case where the RFID receiving device 110 detects location information or entry/exit information of a household member and transmits the detected location information or entry/exit information to the smart energy management system 200, the smart energy management system 200 may receive the location information or entry/exit information of the household member from the RFID receiving device 110. As another example, in a case where the RFID receiving device 110 recognizes an RFID tag of a household member and transmits an identification code of the recognized RFID tag together with identification information of an RFID reader that recognizes the RFID tag to the smart energy management system 200, the smart energy management system 200 may receive the identification code of the RFID tag and the identification information of the RFID reader from the RFID receiving device 110 and detect location information or entry/exit information of the household member.

In operation S320, the smart energy management system 200 may receive energy use details of a household inputted from the home network device 130 in connection with the home network device 130 installed in the household in which the household member resides, and record the received energy use details together with the location information or entry/exit information of the household member, recognized in operation 310. In this instance, the smart energy management system 200 may manage energy use details for each household member based on household member information distinguished according to a code value of the RFID tag.

In operation S330, the smart energy management system 200 may analyze an energy use pattern of the household member for the energy use details based on the location information or entry/exit information of the household member. As an example of a method of detecting an energy use pattern of a household member by analyzing energy use details of the household member, the smart energy management system 200 may analyze a time when a household member enters/exits from/to the outside, and detect that the household member does not use a lighting device in the corresponding time even though the lighting device is turned on or turned off when the household member enters/exits from/to the outside. According to another example, as a method of detecting an energy use pattern of a household member by simply accumulating energy use details of the household member, the smart energy management system may accumulate the energy use amount of a household member by defining a week as a period and detect an energy use pattern of the household member for a predetermined period through an amount of energy used for each period. According to still another example, in a case where a plurality of household members reside in a household, the smart energy management system 200 records energy use details of a corresponding household member for each household member.

In operation S340, the smart energy management system 200 provide energy use details through the home network device 130 as a result obtained by comparing the energy use detailed for each household or so that the household member recognizes the energy use pattern. As an example, the smart energy management system 200 may transmit a result obtained by comparing energy use amounts of households having the same number of household members to the home network device 130 so that the household member can identify the energy use amount and easily recognize the presence of waste of the energy use amount. As another example, in a case where the energy use amount of a household member exceeds a predetermined value and the household member does not operate a home appliance through the home network device 130 due to a predetermined condition, the smart energy management system 200 may determine that the household member is indifferent to energy management, and directly control home appliances through the home network device 130, thereby guiding the household member to save energy. As still another example, in a case where the excess of an energy use amount in a specific household is not determined as being indifferent to saving energy, the smart energy management system 200 does not perform a direct control of a home appliance but controls the home network device 130 to inform that the energy use amount of the specific household is greater than that of another household. As still another example, the smart energy management system may simply provide an energy use pattern of a household member in a graphic form through the home network device 130 so that the household member can monitor his/her own energy use pattern. As still another example, the smart energy management system 200 may transmit control information based on an energy use pattern of a household member to the home network device 130. In this instance, the home network device 130 may automatically control home appliances in a household based on the control information received from the smart energy management system 200.

As described above, according to embodiments of the present invention, the location or presence of entry/exit of a household member in a household is detected, and energy use details of the corresponding household are recorded, so that an energy use pattern of the household member can be easily detected based on the location or presence of entry/exit of the household member. Thus, home appliances in the household are automatically controlled to be suitable for the energy use pattern detected from the energy use details of the household member, so that a home network service optimized to the household member may be provided.

Also, an energy use pattern for a plurality of household members are separately managed by combining energy use details for each household member in a household in which the household members reside, so that energy in an optimized state even when several household members reside may be managed.

Also, a result obtained by comparing an energy use amount of a household with an energy use amount of another household is provided, so that a motive for energy saving may be provided to a household member using a large amount of energy, and a household indifferent to energy management may be guided to save energy in an active manner.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A smart energy management system linked with home network devices respectively installed in a plurality of households to manage the use of energy for each household, the system comprising:
a location detecting unit to detect location information or entry/exit information of a household member through recognition of a radio frequency identification (RFID) tag carried by the household member in connection to an RFID receiving device;
an energy recording unit to receive energy use details of the household in which the household member resides, inputted from the home network device, and to record the received energy use details together with the location information or entry/exit information of the household member;
a pattern analysis unit to analyze an energy use pattern for the energy use details based on the location information or entry/exit information; and
an energy management unit to provide the energy use details through the home network device as a result obtained by comparing the energy use detailed for each household or so that the household member recognizes the energy use pattern.

2. The system of claim 1, wherein the energy recording unit records the energy use details for each household member with respect to a plurality of household members that reside in the household, and the pattern analysis unit manages energy use patterns for the plurality of household members by combining the energy use details recorded for each household.

3. The system of claim 1, wherein, when the energy use amount of the household exceeds a predetermined value and the household member does not operate a home appliance through the home network device due to a predetermined condition, the energy management unit directly controls the home appliance through the home network device.

4. A smart energy management method of a smart energy management system linked with home network devices respectively installed in a plurality of households to manage the use of energy for each household, the method comprising:
detecting location information or entry/exit information of a household member by recognizing an RFID tag carried by the household member through an RFID receiving device;
receiving energy use details of the household in which the household member resides, inputted from the home network device, and recording the received energy use details together with the location information or entry/exit information of the household member;
analyzing an energy use pattern for the energy use details based on the location information or entry/exit information; and
providing the energy use details through the home network device as a result obtained by comparing the energy use detailed for each household or so that the household member recognizes the energy use pattern.
